(19) United States
(12) Patent Application Publication
(10) Pub. No.: US 2009/0045483 A1
(43) Pub. Date: Feb. 19, 2009

(54) Semiconductor devices having trench isolation regions and methods of manufacturing semiconductor devices having trench isolation regions

(75) Inventors: Sang-Ho Rha, Seoul (KR); Eun-Kee Hong, Seongnam-si (KR); Kyung-Mun Byun, Seoul (KR); Jong-Wan Choi, Suwon-si (KR); Eun-Kyung Baek, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/222,630

(22) Filed: Aug. 13, 2008

(30) Foreign Application Priority Data
Aug. 13, 2007 (KR) 10-2007-0081366

(51) Int. Cl. H01L 21/762; H01L 23/58

(52) U.S. Cl. 257/513; 438/434; 257/E23.002; 257/E21.551

(57) ABSTRACT

A semiconductor device may include a semiconductor substrate, trench region, buffer pattern, gap fill layer, and transistor. The trench region may be provided in the semiconductor substrate to define an active region. The buffer pattern and gap fill layer may be provided in the trench region. The buffer pattern and gap fill layer may fill the trench region. The gap fill layer may be densified by the buffer pattern. The transistor may be provided in the active region. A method of manufacturing a semiconductor device may include: forming a trench region in a semiconductor substrate; forming a buffer layer on an inner wall of the first trench region; forming a gap fill layer, filling the trench region; performing a thermal process to react the impurity with the oxygen, forming a buffer pattern; and forming a transistor in the active region.

### PRIORITY STATEMENT

This application claims priority from Korean Patent Application No. 10-2007-0081366, filed on Aug. 13, 2007, in the Korean Intellectual Property Office (KIPO), the entire contents of which are incorporated herein by reference.

### BACKGROUND

1. Field

Example embodiments relate to semiconductor devices and/or methods of manufacturing semiconductor devices. Also, example embodiments relate to semiconductor devices having trench isolation regions and/or methods of manufacturing semiconductor devices having trench isolation regions.

2. Description of Related Art

In view of high integration density, an isolation technique enabling separate devices to be electrically and/or structurally separated from each other to independently perform given functions without being interrupted by adjacent devices may be an essential technique, together with a technique for reducing the separate devices in size. That is, in order to increase integration density of a semiconductor device, dimensions of separate devices should be reduced, and simultaneously, the width and area of an isolation region existing between devices should be reduced to meet the demand for highly integrated semiconductor device. The isolation technique may be important in terms of determining the integration density of a semiconductor device and/or reliability of electrical performance of such a device.

A trench isolation technique that may be widely used for manufacturing a semiconductor device may include forming a trench region defining an active region, and then filling the trench region with an insulating material to isolate the devices from each other. Generally, a trench isolation region that may be formed by a trench isolation technique may be formed of a high-density plasma (HDP) oxide layer. However, as a semiconductor device may become more highly integrated, the width of the trench region may get narrower. Thus, an aspect ratio of the trench region also may be increased. As a result, there may be a limit in filling the trench region with the HDP oxide layer without any void.

### SUMMARY

Example embodiments may provide semiconductor devices having trench isolation regions.

Example embodiments also may provide methods of manufacturing semiconductor devices having trench isolation regions.

According to example embodiments, a semiconductor device may include: a semiconductor substrate; a first trench region; a first buffer pattern; a first gap fill layer; and/or a first transistor. The first trench region may be in the semiconductor substrate to define a first active region. The first buffer pattern may be in the first trench region. The first gap fill layer may be in the first trench region. The first buffer pattern and the first gap fill layer may fill the first trench region. The first gap fill layer may be densified by the first buffer pattern. The first transistor may be in the first active region.

According to example embodiments, a method of manufacturing a semiconductor device may include: forming a first trench region defining a first active region in a semiconductor substrate; forming a first buffer layer including a first impurity on an inner wall of the first trench region; forming a first gap fill layer, filling the first trench region on the first buffer layer; performing a thermal process in a gas ambient including oxygen to react the first impurity in the first buffer layer with the oxygen, forming a first buffer pattern; and/or forming a first transistor in the first active region. The first buffer pattern may densify the first gap fill layer.

According to example embodiments, a method of manufacturing a semiconductor device may include: forming a first trench region defining a first active region in a semiconductor substrate; forming a first buffer spacer including a first impurity on a sidewall of the first trench region; forming a first gap fill layer, filling the first trench region on the first buffer spacer; performing a thermal process in a gas ambient including oxygen to react the first impurity in the first buffer spacer with the oxygen, forming a first buffer pattern; and/or forming a first transistor in the first active region. The first buffer pattern may densify the first gap fill layer.

According to example embodiments, a method of manufacturing a semiconductor device may include: forming a first trench region defining a first active region in a semiconductor substrate; forming a first gap fill layer in the first trench region; doping a first impurity into the first gap fill layer to form a first buffer region; performing a thermal process in a gas ambient including oxygen to react the first impurity in the first buffer region with the oxygen, forming a first buffer pattern; and/or forming a first transistor in the first active region. The first buffer pattern may densify the first gap fill layer.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIGS. 1A to 1F are cross-sectional views of a semiconductor device according to example embodiments;

FIGS. 2A to 2D are cross-sectional views of a semiconductor device according to example embodiments; and

FIGS. 3A to 3C are cross-sectional views of a semiconductor device according to example embodiments.

### DETAILED DESCRIPTION OF EXAMPLE EMBODIMENTS

Example embodiments will now be described more fully with reference to the accompanying drawings. Embodiments, however, may be embodied in different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions are exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

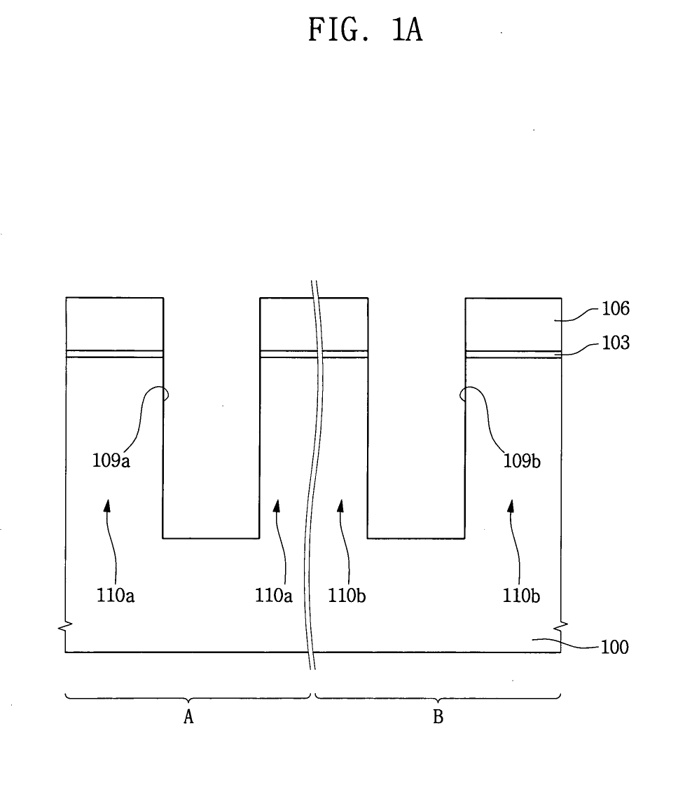

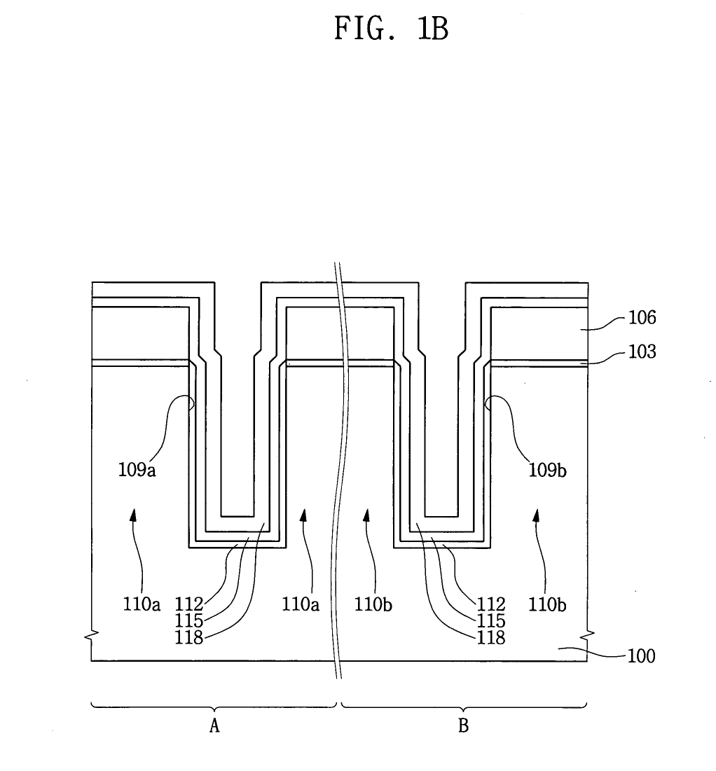

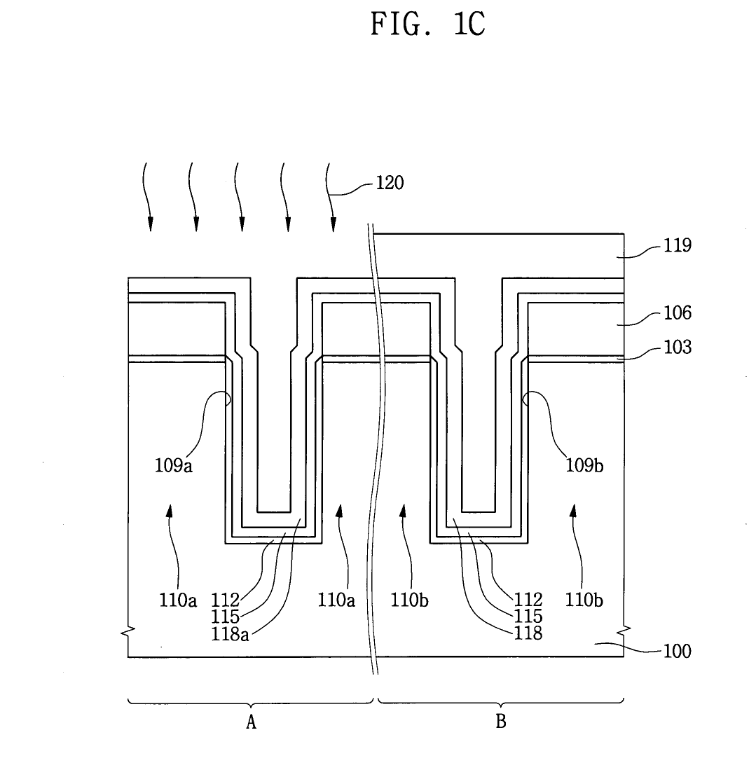

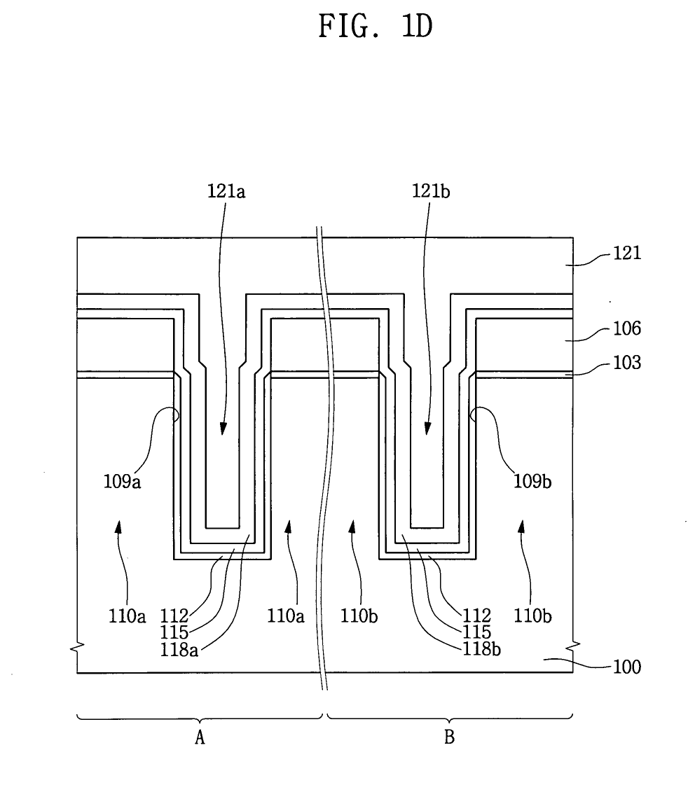

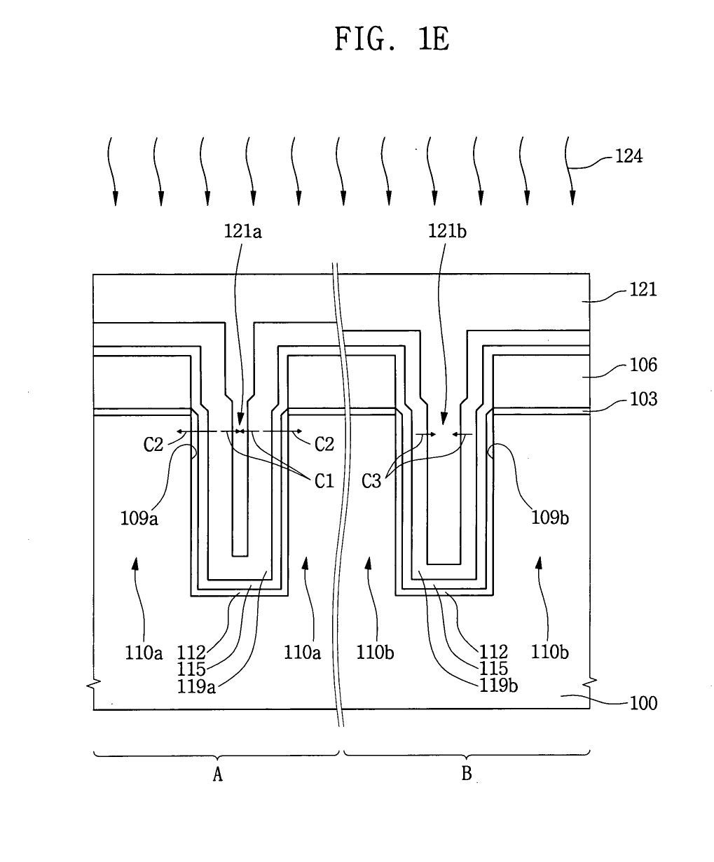

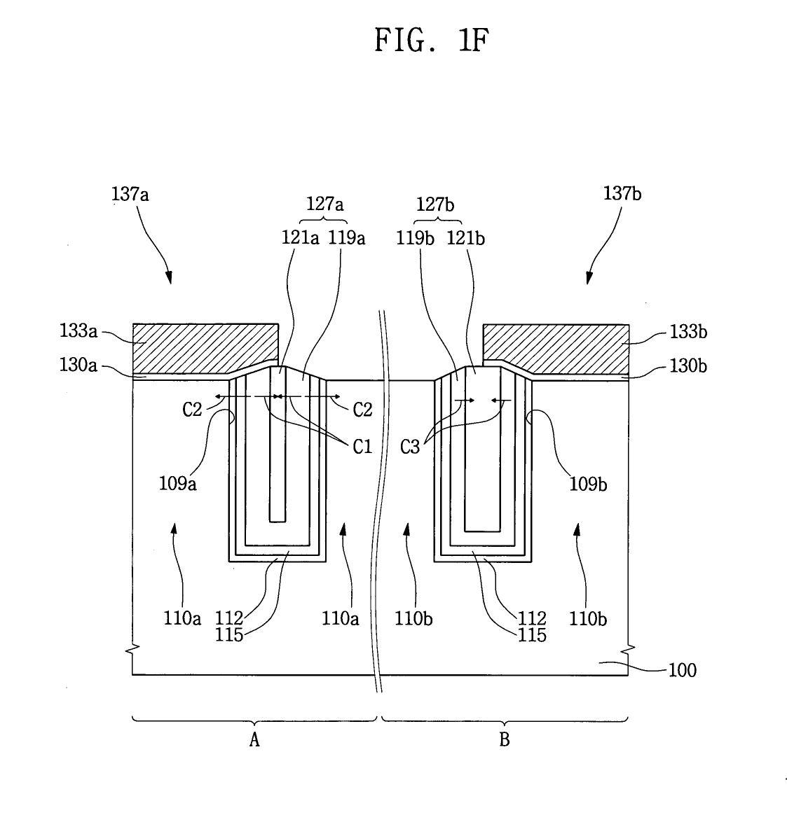

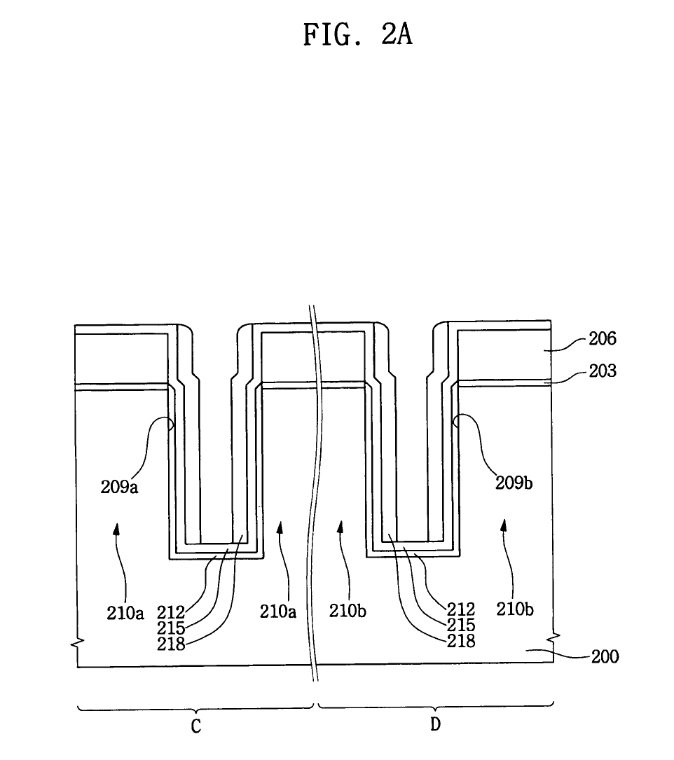

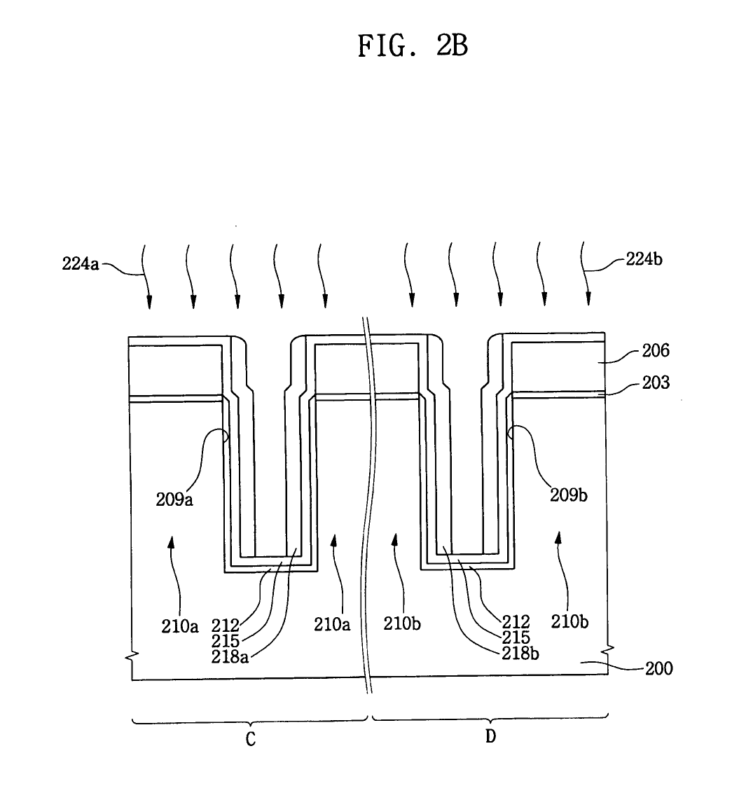

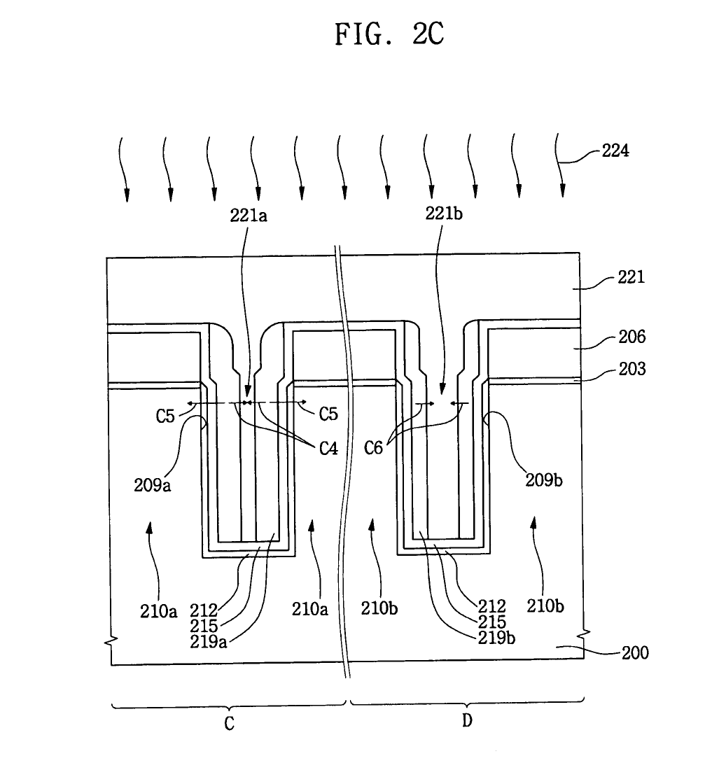

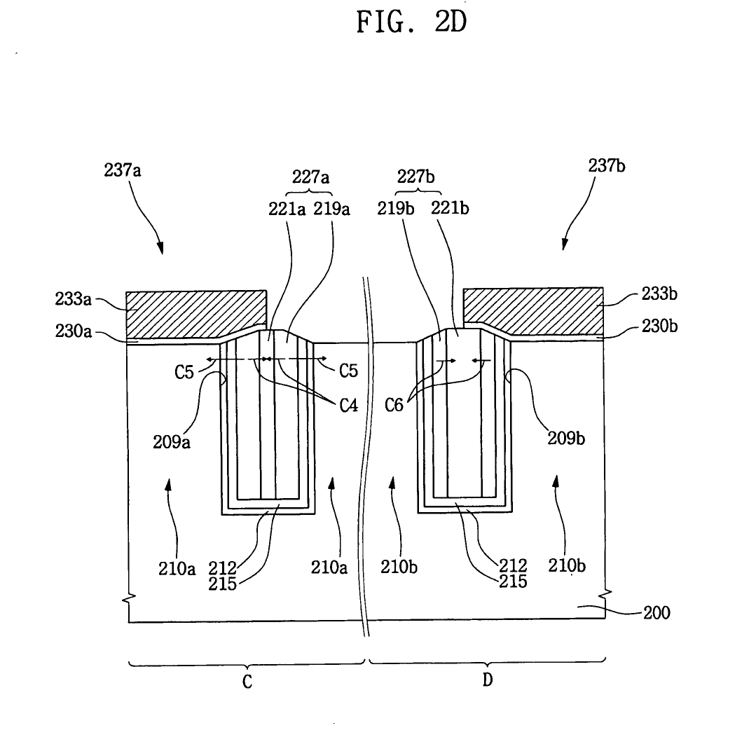

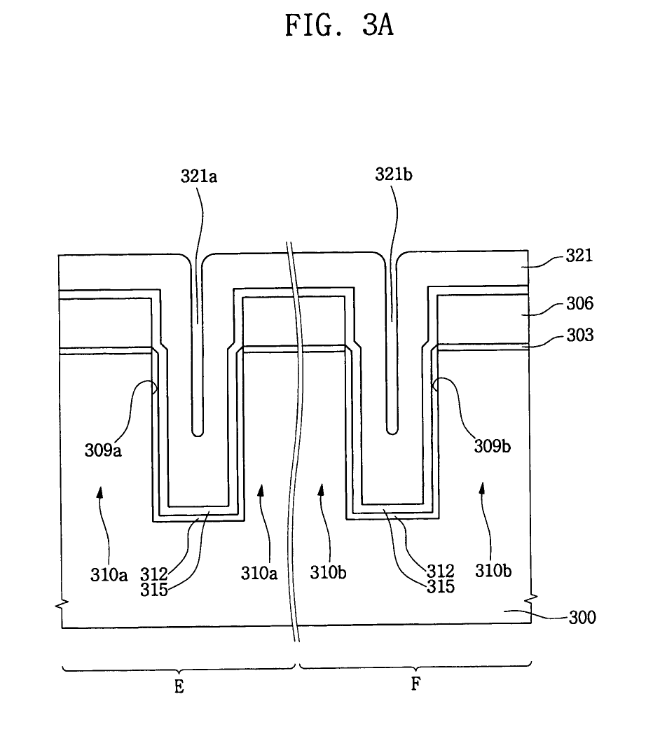

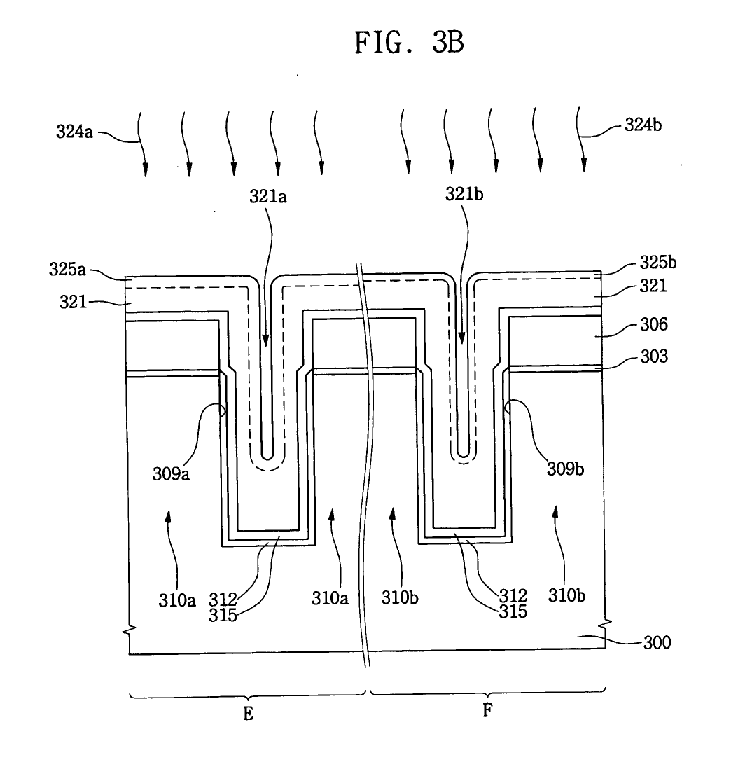

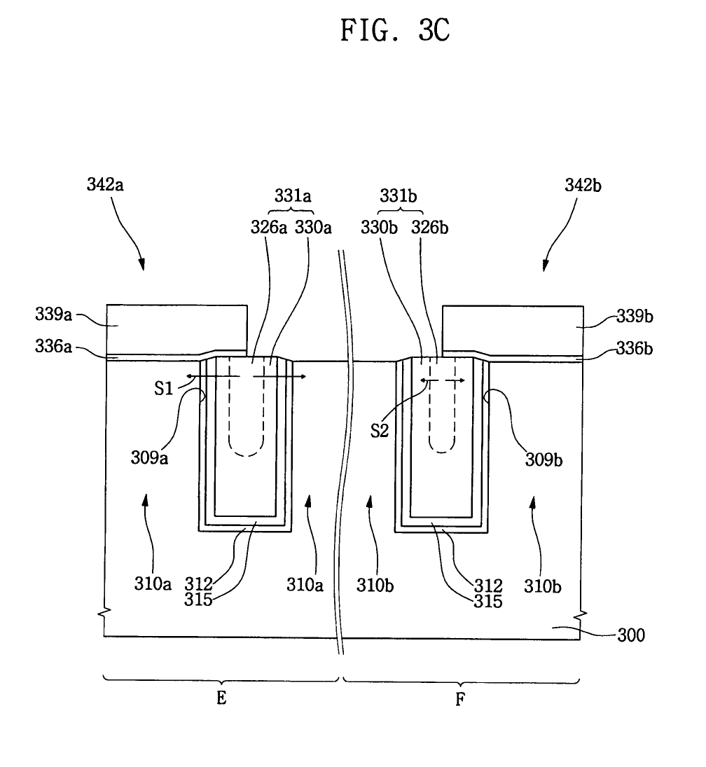

FIGS. 1A to 1F are cross-sectional views of a semiconductor device according to example embodiments, FIGS. 2A to 2D are cross-sectional views of a semiconductor device according to example embodiments, and FIGS. 3A to 3C are cross-sectional views of a semiconductor device according to example embodiments.

In FIGS. 1A to 1F, reference mark “A” may represent a first circuit region and reference mark “B” may represent a second circuit region. In FIGS. 2A to 2D, reference mark “C” may represent a third circuit region and reference mark “D” may represent a fourth circuit region. In FIGS. 3A to 3C, reference mark “E” may represent a fifth circuit region and reference mark “F” may represent a sixth circuit region.

The structure of a semiconductor device according to example embodiments will be described below with reference to FIG. 1F.

Referring to FIG. 1F, substrate 100 having first circuit region A and/or second circuit region B may be provided. Substrate 100 may be a semiconductor substrate, such as a silicon wafer. First trench region 109a, defining first active region 110a, may be provided in substrate 100 of first circuit region A. Second trench region 109b, defining second active region 110b, may be provided in substrate 100 of second circuit region B. First trench region 109a and/or second trench region 109b may have a rectangular shape whose upper region and lower region have the same width. However, the shape is not (or the shapes are not) limited to rectangles, other shapes are possible. For example, first trench region 109a and/or second trench region 109b may have a variety of shapes (e.g., a reverse-trapezoid shape whose upper part may be wider than a lower part, a trapezoid shape having an upper part narrower than a lower part, etc.).

Insulating liner 115 may be provided on inner walls of first trench region 109a and/or second trench region 109b. Insulating liner 115 may be, for example, a SiN layer, a SiC layer, a SiCN layer, or a SiCO layer, that may have insulating characteristics. Thermal oxide layer 112 may be interposed between first trench region 109a and/or second trench region 109b and insulating liner 115.

First buffer pattern 119a may be provided on insulating liner 115 of first trench region 109a. First buffer pattern 119a may be an oxide layer. For example, first buffer pattern 119a may be an oxide layer including silicon and/or oxygen. First buffer pattern 119a may include, for example, at least one of boron (B), phosphorus (P), arsenic (As), germanium (Ge), nitrogen (N), and indium (In), in addition to silicon and/or oxygen. Second buffer pattern 119b may be provided on insulating liner 115 of second trench region 109b. Second buffer pattern 119b may be an oxide layer. For example, second buffer pattern 119b may be an oxide layer including silicon and/or oxygen. Second buffer pattern 119b may include at least one of boron (B), phosphorus (P), arsenic (As), germanium (Ge), nitrogen (N), and indium (In), in addition to silicon and/or oxygen. First buffer pattern 119a may be, for example, thicker than second buffer pattern 119b. According to example embodiments, second buffer pattern 119b may be omitted.

First gap fill layer 121a, filling first trench region 109a and/or densified by first buffer pattern 119a, may be provided on first buffer pattern 119a. Second gap fill layer 121b, filling second trench region 109b and/or densified by second buffer pattern 119b, may be provided on second buffer pattern 119b. First gap fill layer 121a may be provided to have a denser film quality structure than second gap fill layer 121b. First gap fill layer 121a and second gap fill layer 121b may be formed of the same material. For example, first gap fill layer 121a and/or second gap fill layer 121b may be formed of an SOG layer.

First trench isolation region 127a, including first buffer pattern 119a and/or first gap fill layer 121a, may be provided. Also, second trench isolation region 127b, including second buffer pattern 119b and/or second gap fill layer 121b, may be provided. First buffer pattern 119a may densify first gap fill layer 121a, may apply compressive stress C1 to first gap fill layer 121a, and/or may apply compressive stress C2 to first active region 110a. Second buffer pattern 119b may densify second gap fill layer 121b and/or may apply compressive stress C3 to second gap fill layer 121b, but it may not apply a substantial compressive stress to second active region 110b.

First gate dielectric layer 130a and/or first gate electrode 133a, that may be sequentially stacked, may be provided on first active region 110a, and first source and/or drain regions (not shown) may be provided in first active region 110a at one or both sides of first gate electrode 133a. Accordingly, first MOS transistor 137a—including first gate dielectric layer 130a, first gate electrode 133a, and/or the first source and/or drain regions (not shown)—may be provided. First gate dielectric layer 130a may be a thermal oxide layer and/or a high-k dielectric layer.

In addition or in the alternative, second gate dielectric layer 130b and/or second gate electrode 133b, that may be sequentially stacked, may be provided on second active region 110b, and/or second source and/or drain regions (not shown) may be provided in second active region 110b at one or both sides of second gate electrode 133b. Accordingly, second MOS transistor 137b—including second gate dielectric layer 130b, second gate electrode 133b, and/or the second source and/or drain regions (not shown)—may be provided.

According to example embodiments, first MOS transistor 137a may be a PMOS transistor. Therefore, since compressive stress C2 may be applied to a channel region of first active region 110a below first gate electrode 133a, carrier mobility characteristics of first MOS transistor 137a provided may be enhanced.

Second MOS transistor 137b may be an NMOS transistor. Therefore, since second gap fill layer 121b may become dense by second buffer pattern 119b, but compressive stress may not be applied to second active region 110b, a separate device provided in second active region 110b, such as the NMOS transistor, may not be deteriorated in electrical performance.

Therefore, first gap fill layer 121a and/or second gap fill layer 121b may become dense, so that etching resistance of first trench isolation region 127a and/or second trench isolation region 127b may be increased and/or electrical characteristics of a PMOS transistor may be improved without deterioration in electrical characteristic of an NMOS transistor.

The structure of a semiconductor device according example embodiments will be described below with reference to FIG. 2D.

Referring to FIG. 2D, substrate 200, first trench region 209a, second trench region 209b, thermal oxide layer 212, and/or insulating liner 215 (that may be similar to substrate 100, first trench region 109a, second trench region 109b, thermal oxide layer 112, and/or insulating liner 115 described with respect to FIGS. 1A to 1F) may be provided. Substrate 200 may be a semiconductor substrate, such as a silicon wafer. First trench region 209a, defining first active region 210a, may be provided in substrate 200 of third circuit region C. Second trench region 209b, defining second active region 210b, may be provided in substrate 200 of fourth circuit region D. One or both of first trench region 209a and second trench region 209b may have a rectangular shape whose upper region and lower region have the same width. However, the shape is not (or the shapes are not) limited to rectangles, other shapes are possible. For example, first trench region 209a and second trench region 209b may have a variety of shapes (e.g., a reverse-trapezoid shape whose upper part may be wider than a lower part, a trapezoid shape having an upper part narrower than a lower part, etc.).

Insulating liner 215 may be provided on sidewalls of first trench regions 209a and/or second trench region 209b. Insulating liner 215 may be, for example, a SiN layer, a SiC layer, a SiCN layer, or a SiCO layer, that may have insulating characteristics. Thermal oxide layer 212 may be interposed between first trench region 209a and/or second trench region 209b and insulating liner 215.

First buffer pattern 219a may be provided, for example, on insulating liner 215 on a sidewall of first trench region 209a. First buffer pattern 219a may be, for example, an oxide layer. For example, first buffer pattern 219a may be an oxide layer including silicon and/or oxygen. First buffer pattern 219a may include, for example, at least one of boron (B), phosphorus (P), arsenic (As), germanium (Ge), nitrogen (N), and indium (In), in addition to silicon and/or oxygen. Second buffer pattern 219b may be provided on insulating liner 215 on a sidewall of second trench region 209b. Second buffer pattern 219b may be, for example, an oxide layer. For example, second buffer pattern 219b may be an oxide layer including silicon and/or oxygen. Second buffer pattern 219b may include, for example, at least one of boron (B), phosphorus (P), arsenic (As), germanium (Ge), nitrogen (N), and indium (In), in addition to silicon and/or oxygen.

According to example embodiments, second buffer pattern 219b may be omitted.

First gap fill layer 221a, filling first trench region 209a and/or densified by first buffer pattern 219a, may be provided on first buffer pattern 219a. That is, first buffer pattern 219a may be interposed between a sidewall of first trench region 209a and first gap fill layer 221a. In addition or in the alternative, second gap fill layer 221b, filling second trench region 209b and/or densified by second buffer pattern 219b, may be provided on second buffer pattern 219b.

First gap fill layer 221a may have a denser film quality structure than second gap fill layer 221b. First gap fill layer 221a and second gap fill layer 221b may be formed of the same material. For example, first gap fill layer 221a and/or second gap fill layer 221b may be formed of an SOG layer.

First buffer pattern 219a may densify first gap fill layer 221a, may apply compressive stress C4 to first gap fill layer 221a, and/or may apply compressive stress C5 to first active region 210a. Second buffer pattern 219b may densify second gap fill layer 221b and/or may apply compressive stress C6 to second gap fill layer 221b, but it may not apply a substantial compressive stress to second active region 210b.

First trench isolation region 227a—including first buffer pattern 219a and/or first gap fill layer 221a—may be provided (that may be similar to first trench isolation region 127a, first buffer pattern 119a, and/or first gap fill layer 121a described with respect to FIGS. 1A to 1F). In addition or in the alternative, second trench isolation region 227b—including second buffer pattern 219b and/or second gap fill layer 221b—may be provided (that may be similar to second trench isolation region 127b, second buffer pattern 119b, and/or second gap fill layer 121b described with respect to FIGS. 1A to 1F).

First gate dielectric layer 230a and/or first gate electrode 233a, that may be sequentially stacked, may be provided on first active region 210a, and/or first source and/or drain regions (not shown) may be provided in first active region 210a at one or both sides of first gate electrode 233a. Accordingly, first MOS transistor 237a—including first gate dielectric layer 230a, first gate electrode 233a, and/or the first source and/or drain regions (not shown)—may be provided. Similarly, second gate dielectric layer 230b and/or second gate electrode 233b, that may be sequentially stacked, may be provided on second active region 210b, and/or second source and/or drain regions (not shown) may be provided in second active region 210b at one or both sides of second gate electrode 233b. Accordingly, second MOS transistor 237b—including second gate dielectric layer 230b, second gate electrode 233b, and/or the second source and/or drain regions (not shown)—may be provided.

According to example embodiments, first MOS transistor 237a may be a PMOS transistor. Therefore, since a compressive stress may be applied to a channel region of first active region 210a below first gate electrode 233a by first buffer pattern 219a, carrier mobility characteristics of the PMOS transistor provided in first active region 210a may be enhanced.

Second MOS transistor 237b may be an NMOS transistor. Therefore, since second gap fill layer 221b may become dense by second buffer pattern 219b, but a compressive stress may not be applied to second active region 210b, a separate device formed in second active region 210b, such as an NMOS transistor, may not have deteriorated electrical performance, and second trench isolation region 227b having the densified film quality may be provided.

First buffer pattern 219a and/or second buffer pattern 219b may be provided on the sidewalls of first trench region 209a and/or second trench region 209b, and this may prevent stress concentration at corners where the bottom surfaces and sidewalls of first trench region 209a and second trench region 209b meet. As described above, the prevention of stress concentration at corners where the bottom surfaces and sidewalls of first trench region 209a and/or second trench region 209b meet may enhance reliability of the semiconductor device and/or prevent electrical characteristics from being deteriorated.

The structure of a semiconductor device according to example embodiments will be described below with reference to FIG. 3C.

Referring to FIG. 3C, substrate 300 having fifth circuit region E and/or sixth circuit region F may be provided. Substrate 300 may be a semiconductor substrate, such as a silicon wafer. First trench region 309a, defining first active region 310a, may be provided in fifth circuit region E of substrate 300. Second trench region 309b, defining second active region 310b, may be provided in sixth circuit region F of substrate 300. One or both of first trench region 309a and second trench region 309b may have a rectangular shape whose upper region and lower region have the same width. However, the shape is not (or the shapes are not) limited to rectangles, other shapes are possible. For example, first trench region 309a and/or second trench region 309b may have a variety of shapes (e.g., a reverse-trapezoid shape whose upper part may be wider than a lower part, a trapezoid shape having an upper part narrower than a lower part, etc.).

Insulating liner 315 may be provided on sidewalls of first trench region 309a and/or second trench region 309b. Insulating liner 315 may be, for example, a SiN layer, a SiC layer, a SiCN layer, or a SiCO layer, that may have insulating characteristics. Thermal oxide layer 312 may be interposed between first trench region 309a and/or second trench region 309b and insulating liner 315.

First buffer pattern 326a may be provided, for example, in first trench region 309a. First buffer pattern 326a may be, for example, an oxide layer. For example, first buffer pattern 326a may be an oxide layer including silicon and/or oxygen. First buffer pattern 326a may include, for example, at least one of boron (B), phosphorus (P), arsenic (As), germanium (Ge), nitrogen (N), and indium (In), in addition to silicon and/or oxygen.

Second buffer pattern 326b may be provided in second trench region 309b. Second buffer pattern 326b may be, for example, an oxide layer. For example, second buffer pattern 326b may be an oxide layer including silicon and/or oxygen. Second buffer pattern 326b may include, for example, at least one of boron (B), phosphorus (P), arsenic (As), germanium (Ge), nitrogen (N), and indium (In), in addition to silicon and/or oxygen.

First gap fill layer 330a interposed between insulating liner 315 of first trench region 309a and first buffer pattern 326a, and/or densified by first buffer pattern 326a, may be provided. For example, first gap fill layer 330a may be provided to surround the sidewall and/or bottom surfaces of first buffer pattern 326a. First gap fill layer 330a may be a silicon oxide layer. Therefore, first trench isolation region 331a, including first buffer pattern 326a and/or first gap fill layer 330a, may be provided.

In addition or in the alternative, second gap fill layer 330b interposed between insulating liner 315 of second trench region 309b and second buffer pattern 326b, and/or densified by second buffer pattern 326b, may be provided. For example, second gap fill layer 330b may be provided to surround the sidewall and/or bottom surfaces of second buffer pattern 326b. Second gap fill layer 330b may be a silicon oxide layer. Therefore, second trench isolation region 331b, including second buffer pattern 326b and/or second gap fill layer 330b, may be provided.

First buffer pattern 326a may densify first gap fill layer 330a, and/or apply compressive stress S1 to first active region 310a. Second buffer pattern 326b may densify second gap fill layer 330b, but it may not apply a substantial compressive stress to second active region 310b.

First gate dielectric layer 336a and/or first gate electrode 339a, that may be sequentially stacked, may be provided on first active region 310a, and/or first source and/or drain regions (not shown) may be provided in first active region 310a at one or both sides of first gate electrode 339a. As a result, first MOS transistor 342a—including first gate dielectric layer 336a, first gate electrode 339a, and/or the first source and/or drain regions (not shown)—may be provided. Similarly, second gate dielectric layer 336b and/or second gate electrode 339b, that may be sequentially stacked, may be provided on second active region 310b, and/or second source and/or drain regions (not shown) may be provided in second active region 310b at one or both sides of second gate electrode 339b. Accordingly, second MOS transistor 342b—including second gate dielectric layer 336b, second gate electrode 339b, and/or the second source and/or drain regions (not shown)—may be provided.

According to example embodiments, first MOS transistor 342a may be a PMOS transistor. Therefore, since a compressive stress may be applied to a channel region of first active region 310a below first gate electrode 336a by first buffer pattern 326a, carrier mobility characteristics of the PMOS transistor provided in first active region 310a may be enhanced.

According to example embodiments, second MOS transistor 342b may be an NMOS transistor. Therefore, since second gap fill layer 330b may become dense by second buffer pattern 326b, but a substantial compressive stress may not be applied to second active region 310b, a separate device formed in second active region 310b, such as an NMOS transistor, may not have deteriorated electrical performance, and/or second trench isolation region 331b having the densified film quality structure may be provided.

Methods of manufacturing semiconductor devices according to example embodiments will be described below.

A method of manufacturing semiconductor devices according to example embodiments will be described below with reference to FIGS. 1A to 1F.

Referring to FIG. 1A, substrate 100 having first circuit region A and/or second circuit region B may be prepared. Substrate 100 may be a semiconductor substrate, such as a silicon wafer. Pad insulating layer 103 and/or hard mask 106, that may be sequentially stacked, may be formed on one or more regions (that may or may not be predetermined) of substrate 100. Hard mask 106 may be formed to have a silicon nitride layer. Pad insulating layer 103 may be formed to alleviate stress caused by a difference in thermal expansion coefficient between substrate 100 and hard mask 106. For example, pad insulating layer 103 may be a thermal oxide layer.

One or more regions (that may or may not be predetermined) of substrate 100 may be etched using hard mask 106 as an etch mask, so that first trench region 109a may be formed in first circuit region A to define first active region 110a, and/or second trench region 109b may be formed in second circuit region B to define second active region 110b.

First trench region 109a and/or second trench region 109b may have a rectangular shape whose upper region and lower region have the same width. However, the shape is not (or the shapes are not) limited to rectangles, other shapes are possible. For example, first trench region 109a and/or second trench region 109b may have a variety of shapes (e.g., a reverse-trapezoid shape whose upper part may be wider than a lower part, a trapezoid shape having an upper part narrower than a lower part, etc.).

Referring to FIG. 1B, thermal oxide layer 112 may be formed on substrate 100 having first trench region 109a and/or second trench region 109b. Thermal oxide layer 112 may be formed by performing a thermal oxidation process on substrate 100 having first trench region 109a and/or second trench region 109b. Etching damage applied to substrate 100 while first trench region 109a and/or second trench region 109b are formed may be cured by forming thermal oxide layer 112.

Insulating liner 115 may be formed on substrate 100 having thermal oxide layer 112. Insulating liner 115 may prevent first active region 110a and/or second active region 110b of substrate 100 from being oxidized by following thermal processes. Insulating liner 115 may be, for example, a SiN layer, a SiC layer, a SiCN layer, or a SiCO layer, that may have insulating characteristics.

Buffer layer 118 may be formed on insulating liner 115. Buffer layer 118 may be formed, for example, of an oxide layer using chemical vapor deposition (CVD) and/or atomic layer deposition (ALD). Buffer layer 118 may be formed on insulating liner 115 so as not to fill first trench region 109a and/or second trench region 109b.

Referring to FIG. 1C, first mask pattern 119, having an opening that may expose buffer layer 118 on first trench region 109a, may be formed on substrate 100 having buffer layer 118. First mask pattern 119 may be formed using a photoresist layer and/or a hard mask having an etch selectivity with respect to buffer layer 118.

First buffer layer 118a may be formed, for example, by doping a first impurity into buffer layer 118 on first trench region 109a exposed by first mask pattern 119 using first doping process 120. The first impurity may be, for example, silicon (Si). First doping process 120 may include doping a first impurity into buffer layer 118 on first trench region 109a using, for example, a tilt ion implantation process and/or a plasma doping process. A concentration of the first impurity in first buffer layer 118a may be greater than or equal to about 1E10 atom/cm³ and less than or equal to about 1E23 atom/cm³.

The tilt ion implantation process may be used, for example, as first doping process 120 to selectively implant a first impurity into one or more regions (that may or may not be predetermined) of buffer layer 118 on first trench region 109a to form first buffer layer 118a. For example, an angle between a direction in which a first impurity ion may be implanted and substrate 100 may be adjusted so that the first impurity may be implanted into buffer layer 118 disposed on a sidewall of first trench region 109a.

According to example embodiments, while the first impurity may be doped into buffer layer 118 on first trench region 109a, at least one of boron (B), phosphorus (P), arsenic (As), germanium (Ge), nitrogen (N), and indium (In) may be doped as well.

Referring to FIG. 1D, first mask pattern 119 may be removed. Then, a second impurity may be doped into buffer layer 118 of second trench region 109b, using a similar method as first doping process 120, to form second buffer layer 118b. A concentration of the second impurity in second buffer layer 118b may be lower than that of the first impurity in first buffer layer 118a. The second impurity may be, for example, silicon (Si).

A process of doping the second impurity into buffer layer 118 of second trench region 109b may be omitted. In this case, buffer layer 118 of second trench region 109b may be defined as second buffer layer 118b.

According to example embodiments, buffer layer 118 of second trench region 109b may be removed using dry and/or wet etching process.

Gap fill layer 121 filling first trench region 109a and/or second trench region 109b may be formed on first buffer layer 118a and/or second buffer layer 118b. Gap fill layer 121 may be formed of an SOG layer. Gap fill layer 121 may be an organic SOG layer and/or an inorganic SOG layer. For example, gap fill layer 121 may be a polysilazane-based inorganic SOG layer. When gap fill layer 121 may be an inorganic SOG layer, spin coating of a liquid solution including SOG material and a solvent may be performed on substrate 100 having first buffer layer 118a and/or second buffer layer 118b. Then, for example, a thermal process may be performed on the spin-coated liquid solution, so that the solvent of the spin-coated liquid solution may be removed, and the liquid solution may be solidified to form gap fill layer 121.

According to example embodiments, gap fill layer 121 filling first trench region 109a may be defined as first gap fill layer 121a, and/or gap fill layer 121 filling second trench region 109b may be defined as second gap fill layer 121b.

Referring to FIG. 1E, thermal process 124 may be performed on substrate 100 having first gap fill layer 121a and/or second gap fill layer 121b. Thermal process 124 may be performed in a gas ambient including oxygen (O). Thermal process 124 may be performed in a gas ambient including, for example, at least one of O₂, O₃, H₂O, N₂O, NO, CO, and CO₂. In addition or in the alternative, thermal process 124 may be performed, for example, at a temperature greater than or equal to about 750° C. and less than or equal to about 1000° C.

Thermal process 124 may include irradiating ultraviolet light and/or electron beam (E-beam) energy onto substrate 100 having first gap fill layer 121a and/or second gap fill layer 121b. In addition or in the alternative, thermal process 124 may be performed, for example, at a temperature greater than or equal to about 400° C. and less than or equal to about 650° C.

The first impurity in first buffer layer 118a may react with oxygen through thermal process 124 to oxidize first buffer layer 118a, so that first buffer pattern 119a may be formed. That is, first buffer pattern 119a may be formed by oxidizing the whole of or a part of first buffer layer 118a so that first buffer pattern 119a may have a larger volume than first buffer layer 118a. As a result, first buffer pattern 119a may apply first compressive stress C1 to first gap fill layer 121a. As a result, first gap fill layer 121a filling first trench region 109a may be caused to have a denser film quality structure by first buffer pattern 119a. In addition or in the alternative, first buffer pattern 119a may apply second compressive stress C2 to first active region 110a.

When second buffer layer 118b includes the second impurity, second buffer layer 118b maybe oxidized during thermal process 124 so that second buffer pattern 119b may be formed. A concentration of the second impurity in second buffer layer 118b may be lower than that of the first impurity in first buffer layer 118a. Therefore, volume of second buffer layer 118b, expanded by thermal process 124, may be smaller than that of expanded first buffer layer 118a. As a result, while second buffer pattern 119b, formed by expanding second buffer layer 118b, may apply compressive stress C3 to second gap fill layer 121b in second trench region 109b to densify second gap fill layer 121b, it may be formed not to apply a substantial compressive stress to second active region 110b.

Referring to FIG. 1F, gap fill layer 121 may be planarized until hard mask 106 may be exposed. As a result, first gap fill layer 121a may remain in first trench region 109a and/or second gap fill layer 121b may remain in second trench region 109b. Subsequently, hard mask 106 and/or pad insulating layer 103 may be removed.

Therefore, first trench isolation region 127a, including first buffer pattern 119a and/or first gap fill layer 121a, may be formed in first trench region 109a, and/or second trench isolation region 127b, including second buffer pattern 119b and/or second gap fill layer 121b, may be formed in second trench region 109b.

First gate dielectric layer 130a and/or first gate electrode 133a, that may be sequentially stacked, may be formed on first active region 110a, and/or first source and/or drain regions (not shown) may be formed in first active region 110a at one or both sides of first gate electrode 133a. For example, first MOS transistor 137a—including first gate dielectric layer 130a, first gate electrode 133a, and/or the first source and/or drain regions (not shown)—may be formed. First gate dielectric layer 130a may be formed of a thermal oxide layer and/or a high-k dielectric layer. First MOS transistor 137a may be, for example, a PMOS transistor.

Second gate dielectric layer 130b and/or second gate electrode 133b, that may be sequentially stacked, may be formed on second active region 110b, and/or second source and/or drain regions (not shown) may be formed in second active region 110b at one or both sides of second gate electrode 133b. For example, second MOS transistor 137b—including second gate dielectric layer 130b, second gate electrode 133b, and/or the second source and/or drain regions (not shown)—may be formed. Second MOS transistor 137b may be, for example, an NMOS transistor.

A method of manufacturing a semiconductor device according to example embodiments will be described below with reference to FIGS. 2A to 2D.

Referring to FIG. 2A, pad insulating layer 203 and/or hard mask 206, that may be sequentially stacked, may be formed on substrate 200 (using methods that may be similar to those described with respect to FIGS. 1A to 1F), and substrate 200 may be etched using hard mask 206 as an etch mask to form first trench region 209a and/or second trench region 209b, and/or to sequentially form thermal oxide layer 212, insulating liner 215, and/or buffer layer 218. Then, the buffer layer 218 (similar to buffer layer 118 of FIG. 1B) may be anisotropically etched to form buffer spacer 218 remaining on a sidewall of first trench region 209a and/or a sidewall of second trench region 209b.

According to example embodiments, buffer spacer 218 of second trench region 209b may be removed using dry and/or wet etching process.

Referring to FIG. 2B, first doping process 224a (that may be similar to first doping process 120 described with respect to FIGS. 1A to 1F) may be performed to dope a first impurity into buffer spacer 218 on the sidewall of first trench region 209a, so that first buffer spacer 218a may be formed. A concentration of the first impurity in first buffer spacer 218a may be greater than or equal to about 1E10 atom/cm³ and less than or equal to about 1E23 atom/cm³. The first impurity may be, for example, silicon (Si).

While first doping process 224a may be performed, substrate 200 of fourth circuit region D may be covered by a first mask pattern. The first mask pattern may be removed, for example, after performing first doping process 224a.

First buffer spacer 218a may be doped, for example, with at least one of boron (B), phosphorus (P), arsenic (As), germanium (Ge), nitrogen (N), and indium (In). At least one of boron (B), phosphorus (P), arsenic (As), germanium (Ge), nitrogen (N), and indium (In) may be doped into buffer spacer 218, together with the first impurity, to form first buffer spacer 218a.

Second doping process 224b may be performed to dope a second impurity into buffer spacer 218 on the sidewall of second trench region 209b, so that second buffer spacer 218b may be formed. A concentration of the second impurity in second buffer spacer 218b may be lower than that of the first impurity in first buffer spacer 218a. The second impurity may be, for example, silicon (Si).

Second buffer spacer 218b may be doped, for example, with at least one of boron (B), phosphorus (P), arsenic (As), germanium (Ge), nitrogen (N), and indium (In). At least one of boron (B), phosphorus (P), arsenic (As), germanium (Ge), nitrogen (N), and indium (In) may be doped into buffer spacer 218, together with the second impurity, to form second buffer spacer 218b.

Referring to FIG. 2C (that may be similar to gap fill layer 121, first trench region 109a, and/or second trench region 109b described with respect to FIGS. 1A to 1F), gap fill layer 221 filling first trench region 209a and/or second trench region 209b may be formed. In example embodiments, gap fill layer 221 filling first trench region 209a may be defined as first gap fill layer 221a, and/or gap fill layer 221 filling second trench region 209b may be defined as second gap fill layer 221b.

Subsequently, thermal process 224 (that may be similar to thermal process 124 described with respect to FIGS. 1A to 1F) may be performed, and as a result, the first impurity in first buffer spacer 218a may react with oxygen so that first buffer spacer 218a may be oxidized to form first buffer pattern 219a. That is, the volume of first buffer spacer 218a may be expanded so that first buffer pattern 219a may be formed, and as a result, first compressive stress C4 may be applied to first gap fill layer 221a filling first trench region 209a. Therefore, first gap fill layer 221a may be caused to have a denser film quality structure by first buffer pattern 219a. In addition or in the alternative, first buffer pattern 219a may apply second compressive stress C5 to first active region 210a.

When second buffer spacer 218b includes the second impurity, second buffer spacer 218b may be oxidized to form second buffer pattern 219b during thermal process 224. In example embodiments, the concentration of the second impurity in second buffer spacer 218b may be lower than that of the first impurity in first buffer spacer 218a. Therefore, the volume of second buffer spacer 218b, expanded by thermal process 224, may be smaller than that of expanded first buffer spacer 218a. Therefore, while second buffer pattern 219b, formed by expanding second buffer spacer 218b, may apply compressive stress C6 to second gap fill layer 221b in second trench region 209b to densify second gap fill layer 221b, it may not apply a substantial compressive stress to second active region 210b.

Referring to FIG. 2D (that may be similar to gap fill layer 121, hard mask 106, and/or pad insulating layer 103 described with respect to FIGS. 1A to 1F), gap fill layer 221 may be planarized until hard mask 206 may be exposed, and/or hard mask 206 and/or pad insulating layer 203 may be removed. As a result, first gap fill layer 221a may remain in first trench region 209a, and/or second gap fill layer 221b may remain in second trench region 209b. Accordingly, first trench isolation region 227a, including first buffer pattern 219a and/or first gap fill layer 221a, may be formed in first trench region 209a, and/or second trench isolation region 227b, including second buffer pattern 219b and/or second gap fill layer 221b, may be formed in second trench region 209b.

In example embodiments (that may be similar to first gate dielectric layer 130a, first gate electrode 133a, first active region 110a, second gate dielectric layer 130b, second gate electrode 133b, and/or second active region 110b described with respect to FIGS. 1A to 1F), first gate dielectric layer 230a and/or first gate electrode 233a, that may be sequentially stacked, may be formed on first active region 210a, and/or first source and/or drain regions (not shown) may be formed in first active region 210a at one or both sides of first gate electrode 233a. Accordingly, first MOS transistor 237a—including first gate dielectric layer 230a, first gate electrode 233a, and/or the first source and/or drain regions (not shown)—may be formed. First MOS transistor 237a may be, for example, a PMOS transistor. Similarly, second gate dielectric layer 230b and/or second gate electrode 233b, that may be sequentially stacked, may be formed on second active region 210b, and second source and/or drain regions (not shown) may be formed in second active region 210b at one or both sides of second gate electrode 233b. Accordingly, second MOS transistor 237b—including second gate dielectric layer 230b, second gate electrode 233b, and/or the second source and/or drain regions (not shown)—may be formed. Second MOS transistor 237b may be, for example, an NMOS transistor.

A method of manufacturing a semiconductor device according to example embodiments will be described below with reference to FIGS. 3A to 3C.

Referring to FIG. 3A, substrate 300 having fifth circuit region E and/or sixth circuit region F may be prepared. Substrate 300 may be a semiconductor substrate, such as a silicon wafer. Pad insulating layer 303 and/or hard mask 306, that may be sequentially stacked, may be formed on one or more regions (that may or may not be predetermined) of substrate 300. The one or more regions of substrate 300 may be etched using hard mask 306 as an etch mask to form first trench region 309a in fifth circuit region E and/or second trench region 309b in sixth circuit region F, so that first active region 310a and/or second active region 310b may be defined.

Thermal oxide layer 312 may be formed on substrate 300 having first trench region 309a and/or second trench region 309b. Insulating liner 315 may be formed on substrate 300 having thermal oxide layer 312. Insulating liner 315 may prevent substrate 300 of first active region 310a and/or second active region 310b from being oxidized by following thermal processes. Insulating liner 315 may be formed, for example, of a SiN layer, a SiC layer, a SiCN layer, or a SiCO layer, that may have insulating characteristics.

Gap fill layer 321, filling first trench region 309a and/or second trench region 309b, may be formed on substrate 300 having insulating liner 315. Gap fill layer 321 may be formed to have recessed regions 321a and/or 321b. For example, when gap fill layer 321 may be formed of an insulating material layer such as an undoped silicate glass (USG) layer, gap fill layer 321 may have recessed region 321a in first trench region 309a and/or recessed region 321b in second trench region 309b. Recessed region 321a and/or recessed region 321b of gap fill layer 321 may be exposed.

When recessed region 321a and/or recessed region 321b of gap fill layer 321 may not be exposed, and/or may be disposed in gap fill layer 321 in the shaped of a void, gap fill layer 321 may be planarized to expose recessed region 321a and/or recessed region 321b. Accordingly, gap fill layer 321 may have recessed region 321a and/or recessed region 321b that may be recessed downwardly from an upper surface.

Referring to FIG. 3B, in fifth circuit region E, first doping process 324a may be performed (that may be similar to first doping process 120 described with respect to FIGS. 1A to 1F), and thus a first impurity may be doped into gap fill layer 321 adjacent to at least a sidewall of recessed region 321a to form first buffer region 325a. A concentration of the first impurity in first buffer region 325a may be greater than or equal to about 1E10 atom/cm³ and less than or equal to about 1E23 atom/cm³. The first impurity may be, for example, silicon (Si).

While first doping process 324a may be performed, substrate 300 of sixth circuit region F may be covered with a first mask pattern. The first mask pattern may be removed, for example, after performing first doping process 324a.

According to example embodiments, while the first impurity may be doped into gap fill layer 321 on first trench region 309a, at least one of boron (B), phosphorus (P), arsenic (As), germanium (Ge), nitrogen (N), and indium (In) may be doped as well. Therefore, first buffer region 325a may include at least one of boron (B), phosphorus (P), arsenic (As), germanium (Ge), nitrogen (N), and indium (In), together with the first impurity.

In sixth circuit region F, second doping process 324b may be performed to dope a second impurity into gap fill layer 321 adjacent to at least a sidewall of recessed region 321b to form second buffer region 325b. A concentration of the second impurity in second buffer region 325b may be lower than that of the first impurity in first buffer region 325a. The second impurity may be, for example, silicon (Si).

According to example embodiments, while the second impurity may be doped into gap fill layer 321 on second trench region 309b, at least one of boron (B), phosphorus (P), arsenic (As), germanium (Ge), nitrogen (N), and indium (In) may be doped as well. Therefore, second buffer region 325b may include at least one of boron (B), phosphorus (P), arsenic (As), germanium (Ge), nitrogen (N), and indium (In), together with the second impurity.

Referring to FIG. 3C, a thermal process 324 (that may be similar to thermal process 124 described with respect to FIGS. 1A to 1F) may be performed on substrate 300 having first buffer region 325a and/or second buffer region 325b, to oxidize first buffer region 325a and/or second buffer region 325b, so that first buffer pattern 326a and/or second buffer pattern 326b, whose volumes may be expanded, may be formed. Therefore, gap fill layer 321 may become dense by first buffer pattern 326a and/or second buffer pattern 326b. In this case, the recessed region (refer to 321a and/or 321b of FIG. 3B) may be filled with first buffer pattern 326a and/or second buffer pattern 326b.

Since a concentration of the first impurity in the first buffer region (refer to 325a of FIG. 3B) may be higher than that of the second impurity in the second buffer region (refer to 325b of FIG. 3B), gap fill layer 321 may become denser by first buffer pattern 326a as compared to second buffer pattern 326b.

According to example embodiments, gap fill layer 321 in first trench region 309a may be defined as first gap fill layer 330a, and/or gap fill layer 321 in second trench region 309b may be defined as second gap fill layer 330b.

First buffer pattern 326a may be formed to densify first gap fill layer 321a and/or to apply compressive stress S1 to first active region 310a. In contrast, while second buffer pattern 326b may apply compressive stress S2 sufficient to densify second gap fill pattern 321b, it may not apply a substantial compressive stress to second active region 310b.

The recessed region (refer to 321a of FIG. 3B) of the gap fill layer (refer to 321 of FIG. 3B) of first trench region 309a may be filled by first buffer pattern 326a. Therefore, first trench region 309a may be filled by first buffer pattern 326a and/or first gap fill layer 330a. First buffer pattern 326a and/or first gap fill layer 330a may constitute first trench isolation region 331a. In addition or in the alternative, the recessed region (refer to 321b of FIG. 3B) of the gap fill layer (refer to 321 of FIG. 3B) of second trench region 309b may be filled by second buffer pattern 326b. Therefore, second trench region 309b may be filled by second buffer pattern 326b and/or second gap fill layer 330b. Second buffer pattern 326b and/or second gap fill layer 330b may constitute second trench isolation region 331b.

First gate dielectric layer 336a and/or first gate electrode 339a, that may be sequentially stacked, may be formed on first active region 310a, and/or first source and/or drain regions (not shown) may be formed in first active region 310a at one or both sides of first gate electrode 339a. Accordingly, first transistor 342a—including first gate dielectric layer 336a, first gate electrode 339a, and/or the first source and/or drain regions (not shown)—may be formed. First transistor 342a may be, for example, a PMOS transistor. Similarly, second gate dielectric layer 336b and/or second gate electrode 339b, that may be sequentially stacked, may be formed on second active region 310b, and/or second source and/or drain regions (not shown) may be formed in second active region 310b at one or both sides of second gate electrode 339b. Accordingly, second transistor 342b—including second gate dielectric layer 336b, second gate electrode 339b, and/or the second source and/or drain regions (not shown)—may be formed. Second transistor 342b may be, for example, an NMOS transistor.

According to example embodiments, a semiconductor device having a trench isolation region including a gap fill layer and/or a buffer pattern may be provided. The buffer pattern may densify the gap fill layer. The buffer pattern may apply a compressive stress to the active region. Also, a PMOS transistor may be provided to the active region where the compressive stress may be applied. Carrier mobility characteristics of the PMOS transistor may be enhanced. Accordingly, one or both of etching resistance of the trench isolation region and electrical characteristics of a semiconductor device may be enhanced.

While example embodiments have been particularly shown and described, it will be understood by those of ordinary skill in the art that various changes in form and details may be made therein without departing from the spirit and scope of the present invention as defined by the following claims.

What is claimed is:

1. A semiconductor device, comprising:
a semiconductor substrate;
a first trench region;
a first buffer pattern;
a first gap fill layer; and
a first transistor;
wherein the first trench region is in the semiconductor substrate to define a first active region,
wherein the first buffer pattern is in the first trench region,
wherein the first gap fill layer is in the first trench region,
wherein the first buffer pattern and the first gap fill layer fill the first trench region,
wherein the first gap fill layer is densified by the first buffer pattern, and
wherein the first transistor is in the first active region.

2. The device of claim 1, wherein the first gap fill layer is on the first buffer pattern.

3. The device of claim 1, wherein the first buffer pattern is between an inner wall of the first trench region and the first gap fill layer.

4. The device of claim 1, wherein the first buffer pattern is between a side wall of the first trench region and the first gap fill layer.

5. The device of claim 1, wherein the first gap fill layer is between an inner wall of the first trench region and the first buffer pattern.

6. The device of claim 1, wherein the first buffer pattern applies compressive stress to the first active region.

7. The device of claim 1, wherein the first transistor is a PMOS transistor.

8. The device of claim 1, further comprising:
an insulating liner;
wherein the insulating liner is along an inner wall of the first trench region.

9. The device of claim 1, further comprising:
a second trench region;
a second buffer pattern;
a second gap fill layer; and
a second transistor;
wherein the second trench region is in the semiconductor substrate to define a second active region separated from the first active region,
wherein the second buffer pattern is in the second trench region,
wherein the second buffer pattern has a thickness less than a thickness of the first buffer pattern,
wherein the second gap fill layer is in the second trench region,
wherein the second buffer pattern and the second gap fill layer fill the second trench region,
wherein the second gap fill layer is densified by the second buffer pattern, and
wherein the second transistor is in the second active region.

10. A method of manufacturing a semiconductor device, comprising:
forming a first trench region defining a first active region in a semiconductor substrate;
forming a first buffer layer including a first impurity on an inner wall of the first trench region;
forming a first gap fill layer, filling the first trench region on the first buffer layer;
performing a thermal process in a gas ambient including oxygen to react the first impurity in the first buffer layer with the oxygen, forming a first buffer pattern; and
forming a first transistor in the first active region;
wherein the first buffer pattern densities the first gap fill layer.

11. The method of claim 10, further comprising:
forming an insulating liner on the inner wall of the first trench region, before forming the first buffer layer.

12. The method of claim 10, wherein the first buffer pattern applies compressive stress to the first active region.

13. The method of claim 10, further comprising:
forming a second trench region, defining a second active region separated from the first active region in the semiconductor substrate, while the first trench region is formed;
forming a second buffer layer including a second impurity on an inner wall of the second trench region while the first buffer layer is formed, wherein a concentration of the second impurity in the second buffer layer is lower than a concentration of the first impurity in the first buffer layer;
forming a second gap fill layer, filling the second trench region on the second buffer layer, while the first gap fill layer is formed;
reacting the second impurity in the second buffer layer with the oxygen to form a second buffer pattern while the thermal process is performed; and
forming a second transistor in the second active region while the first transistor is formed in the first active region;
wherein the second buffer pattern densities the second gap fill layer.

14. A method of manufacturing a semiconductor device, comprising:
forming a first trench region defining a first active region in a semiconductor substrate;
forming a first buffer spacer including a first impurity on a sidewall of the first trench region;
forming a first gap fill layer, filling the first trench region on the first buffer spacer;
performing a thermal process in a gas ambient including oxygen to react the first impurity in the first buffer spacer with the oxygen, forming a first buffer pattern; and
forming a first transistor in the first active region;
wherein the first buffer pattern densities the first gap fill layer.

15. The method of claim 14, further comprising:
forming an insulating liner on an inner wall of the first trench region, before forming the first buffer spacer.

16. The method of claim 14, wherein the first buffer pattern applies compressive stress to the first active region.

17. The method of claim 14, further comprising:
forming a second trench region, defining a second active region separated from the first active region in the semiconductor substrate, while the first trench region is formed;
forming a second buffer spacer including a second impurity on a sidewall of the second trench region while the first buffer spacer is formed, wherein a concentration of the second impurity in the second buffer spacer is lower than a concentration of the first impurity in the first buffer spacer;
forming a second gap fill layer, filling the second trench region on the second buffer spacer, while the first gap fill layer is formed;
reacting the second impurity in the second buffer spacer with the oxygen to form a second buffer pattern while the thermal process is performed; and
forming a second transistor in the second active region while the first transistor is formed;
wherein the second buffer pattern densities the second gap fill layer.

18. A method of manufacturing a semiconductor device, comprising:
forming a first trench region defining a first active region in a semiconductor substrate;
forming a first gap fill layer in the first trench region;
doping a first impurity into the first gap fill layer to form a first buffer region;
performing a thermal process in a gas ambient including oxygen to react the first impurity in the first buffer region with the oxygen, forming a first buffer pattern; and
forming a first transistor in the first active region;
wherein the first buffer pattern densities the first gap fill layer.

19. The method of claim 18, wherein the first buffer pattern applies compressive stress to the first active region.

20. The method of claim 18, further comprising:
forming a second trench region, defining a second active region separated from the first active region in the semiconductor substrate, while the first trench region is formed;
forming a second gap fill layer in the second trench region while the first gap fill layer is formed;
doping a second impurity into the second gap fill layer to form a second buffer region while the first buffer region is formed, wherein a concentration of the second impurity in the second buffer region is lower than a concentration of the first impurity in the first buffer region;
reacting the second impurity in the second buffer region with the oxygen to form a second buffer pattern while the thermal process is performed; and
forming a second transistor in the second active region while the first transistor is formed;
wherein the second buffer pattern densities the second gap fill layer.
